(19) United States
(12) Patent Application Publication
(10) Pub. No.: US 2026/0040971 A1
(43) Pub. Date: Feb. 5, 2026

(54) PACKAGE SUBSTRATE INCLUDING PASSIVE DEVICES EMBEDDED WITH CONTACT SURFACES ORTHOGONAL TO A PLANE OF SUBSTRATE AND RELATED METHODS

(71) Applicant: Microsoft Technology Licensing, LLC, Redmond, WA (US)

(72) Inventor: Christopher CANTALOUBE, Boca Raton, FL (US)

(21) Appl. No.: 18/789,313

(22) Filed: Jul. 30, 2024

(51) Int. Cl. H01L 23/498; H01L 21/768; H01L 23/495; H01L 23/522; H01L 23/528

(52) U.S. Cl. CPC H01L 23/49827; H01L 21/76898; H01L 23/49589; H01L 23/5226; H01L 23/5283

(57) ABSTRACT

Passive devices may be embedded into a cavity in a package substrate, with electrical contacts of the passive device on a contact surface orthogonal to a surface of the package substrate and extending through the package substrate. The electrical contacts of the passive device may be coupled to vias coupled to a power supply to provide capacitive decoupling. One or more through-hole vias (THVs), which provide current to ICs on the package substrate, may be excluded from the package substrate to accommodate the passive device. Embedding the passive devices in the cavity of the package substrate with the contact surface orthogonal to, rather than parallel to, the surface of the package substrate, reduces an area occupied by the passive device. In this manner, a number of the THVs excluded from the package substrate is reduced, which results in a smaller impact to the resistance of the power supply network.

### FIELD OF THE DISCLOSURE

The technology of the disclosure relates, in general, to package substrates such as printed circuit boards and/or cards for integrated circuit packages and, more specifically, to substrates, including decoupling capacitors to improve electrical characteristics thereof.

### BACKGROUND

Electronic computing systems and devices rely on integrated circuits (ICs) to provide functionality and high performance to users. ICs may include analog and digital circuits, such as processor circuits, that employ a large number of semiconductor devices (e.g., transistors) on a semiconductor substrate. However, the ICs do not function in isolation and need to be connected to each other, to external circuits and devices, and to a source of power for the semiconductor devices. In this regard, the ICs are typically mounted on or coupled to a package substrate, which may be a planar, laminated board, or card that includes multiple interconnect layers and electrical vias extending in a thickness direction through the package substrate to provide power and other signals to the ICs. Semiconductor devices may be densely packed on ICs and may consume energy at a high rate. In addition, the power demands of ICs on a package substrate may change quickly. When there is a sudden increase in current draw, the voltage to an IC may temporarily droop before the power source can respond to the increased demand. To mitigate this problem, passive devices, such as decoupling capacitors, may be coupled to the electrical interconnects and vias in the package substrate. The benefit of the passive devices decreases as their distance from the ICs increases. For this reason, the passive devices may be included on the package substrate, as close as possible to the ICs.

### SUMMARY

Exemplary aspects disclosed herein include package substrates, including passive devices embedded with contact surfaces orthogonal to a plane of the substrate. Methods of fabricating the package substrates with contact surfaces of embedded passive devices orthogonal to the substrate plane are also disclosed. The surface of a package substrate may be densely occupied by integrated circuits (ICs), memory chips, and other devices, leaving little room for surface-mounted passive devices. In an exemplary package substrate, passive devices may be embedded into a cavity in the package substrate, with electrical contacts of the passive device on a contact surface orthogonal to the surface of the package substrate and extending through the package substrate. In some examples, the electrical contacts of the passive device may be coupled to vias coupled to a power supply to provide capacitive decoupling. One or more through-hole vias (THVs), which provide current to power the ICs, are excluded from the package substrate to accommodate the passive device. Embedding the passive devices in the cavity of the package substrate with the contact surface orthogonal to, rather than parallel to, the surface of the package substrate reduces an area occupied by the passive device. In this manner, a number of the THVs excluded from the package substrate is reduced, which results in a smaller impact to the resistance of the power supply network in the package substrate.

In one exemplary aspect, a package substrate is disclosed. The package substrate includes a first dielectric material including a first surface extending in a first direction and in a second direction orthogonal to the first direction, the first surface configured to couple to at least one integrated circuit (IC). The package substrate further includes a plurality of through-hole vias (THVs) extending through the first dielectric material in a third direction orthogonal to the first surface and a cavity extending through the first dielectric material in the third direction. The package substrate further includes a passive device, that includes a device substrate, that includes a contact surface, and electrical contacts disposed on the contact surface, wherein the passive device is disposed in the cavity and the contact surface of the device substrate extends in the third direction.

In another exemplary aspect, a method of fabricating a package substrate, including a passive device, is disclosed. The method includes forming a first dielectric material including a first surface extending in a first direction and in a second direction orthogonal to the first direction, the first surface configured to couple to at least one integrated circuit (IC). The method further includes forming a plurality of through-hole vias (THVs) extending through the first dielectric material in a third direction orthogonal to the first surface and forming a cavity in the first dielectric material extending through the first dielectric material in the third direction. The method further includes forming a passive device, including a device substrate that includes a contact surface and electrical contacts disposed on the contact surface. The method further includes disposing the passive device in the cavity with the contact surface of the device substrate extending in the third direction.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1A is a cross-sectional view of a two-dimensional (2D) array of cylindrical through-hole vias (THVs) in a dielectric material of a conventional package substrate;

FIG. 1B is a cross-sectional side view of the package substrate shown in FIG. 1, including a row of the THVs extending through the dielectric material and coupled to interconnect layers disposed on a first surface and a second surface of the dielectric material;

FIG. 2A is a cross-sectional side view of a passive device formed in a device substrate, an electrical contact formed on a contact surface of the device substrate, and a via coupled to the electrical contact;

FIG. 2B is a plan view of the surface of the device substrate of the passive device in FIG. 2A, showing that the passive device includes two electrical contacts coupled to vias, both extending in a same direction;

FIG. 3A is a view of an exemplary package substrate of a dielectric material extending in a first direction and a second direction, including a 2D array of cylindrical THVs and a passive device disposed in a cavity in the dielectric material of the package substrate, the passive device oriented with electrical contacts on a contact surface of a device substrate to reduce a number of cylindrical THVs that are excluded from the package substrate to accommodate the passive device;

FIG. 3B is a cross-sectional view of the exemplary package substrate in FIG. 3A extending in the first direction and a third direction orthogonal to the cross-section shown in FIG. 3A, showing a row in the 2D array of cylindrical THVs extending in the first direction through the dielectric material and a side view of the passive device to show a first electrode coupled to a via formed in the cavity;

FIG. 3C is a cross-sectional view of the exemplary package substrate in FIG. 3A extending in the second direction and the third direction, showing a row in the 2D array of cylindrical THVs extending in the second direction through the dielectric material and a view of a surface of the passive device to show both electrodes coupled to respective vias formed in the cavity;

FIG. 4 is a flowchart illustrating a first exemplary method of fabricating the package substrate in FIGS. 3A-3C;

FIGS. 5A-5E are a flow chart of a second exemplary method of fabricating the package substrate in FIGS. 3A-3C;

FIGS. 6A1-6E1 and 6A2-6E2 are illustrations of cross-sectional views and plan views, respectively, of fabrication stages corresponding to FIGS. 5A-5E; and

FIG. 7 is a block diagram of an exemplary processor-based system that comprises integrated circuit chips disposed on a package substrate that may include the passive device disposed in a cavity, as shown in FIGS. 3A-3C.

### DETAILED DESCRIPTION

With reference to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Exemplary aspects disclosed herein include package substrates, including passive devices embedded with contact surfaces orthogonal to a plane of the substrate. Methods of fabricating the package substrates with contact surfaces of embedded passive devices orthogonal to the substrate plane are also disclosed. The surface of a package substrate may be densely occupied by integrated circuits (ICs), memory chips, and other devices, leaving little room for surface-mounted passive devices. In an exemplary package substrate, passive devices may be embedded into a cavity in the package substrate, with electrical contacts of the passive device on a contact surface orthogonal to the surface of the package substrate and extending through the package substrate. In some examples, the electrical contacts of the passive device may be coupled to vias coupled to a power supply to provide capacitive decoupling. One or more through-hole vias (THVs), which provide current to power the ICs, are excluded from the package substrate to accommodate the passive device. Embedding the passive devices in the cavity of the package substrate with the contact surface orthogonal to, rather than parallel to, the surface of the package substrate reduces an area occupied by the passive device. In this manner, a number of the THVs excluded from the package substrate is reduced, which results in a smaller impact to the resistance of the power supply network in the package substrate.

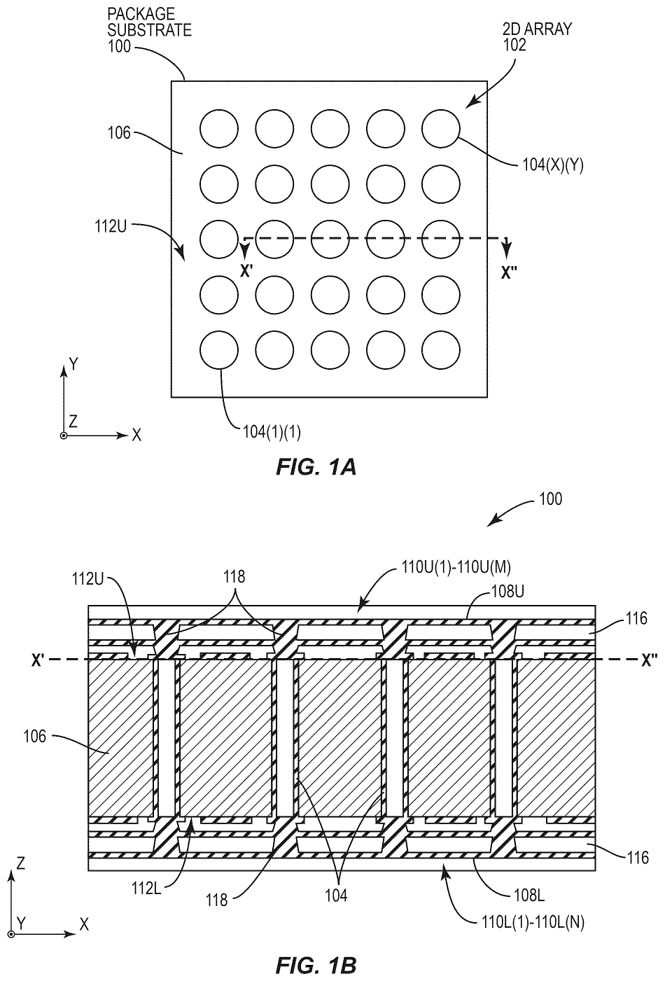

FIG. 1A is a cross-sectional view of a package substrate 100, including a two-dimensional (2D) array 102 of cylindrical THVs 104(1)(1)-104(X)(Y), which may be collectively referred to herein as THVs 104, in a dielectric material 106. FIG. 1B is a cross-sectional side view of the package substrate 100 shown in FIG. 1A, including a row of the THVs 104 extending through the dielectric material 106 and that may be coupled to interconnects 108U in interconnect layers 110U(1)-110U(M) on an upper, first surface 112U of the dielectric material 106. The THVs 104 may also be coupled to interconnects 108L in interconnect layers 110L(1)-110L(N) disposed on a second, lower surface 112L of the dielectric material 106. The view in FIG. 1A is a plan view of the cross-section indicated in FIG. 1B.

The illustrations in FIGS. 1A and 1B are only representative of features of the package substrate 100, which may extend further in a first, X-axis direction and a second, Y-axis direction. Additionally, the 2D array 102 may also extend further in the first (X-axis) and second (Y-axis) directions in the dielectric material 106. The package substrate 100 is configured to couple to integrated circuits (ICs) (not shown) on the first surface 112U and the second surface 112L. More specifically, the package substrate 100 is configured to have at least one IC coupled to the interconnect layers 110U(1)-110U(M). The interconnect layers 110U(1)-110U(M) may comprise multiple layers of metal (e.g., copper) wires or traces extending in the first (X-axis) direction and the second (Y-axis) direction and separated from each other in a third (Z-axis) direction by an inter-layer dielectric material 116. The interconnects 108U are formed in the interconnect layers 110U(1)-110U(M), and the interconnects 108U in one of the interconnect layers 110U(1)-110U (M) may be coupled to interconnects 108U in other interconnect layers 110U(1)-110U(M) in the third direction by vias 118. The interconnects 108U may also be coupled to one or more of the THVs 104. On the second surface 112L of the package substrate 100, the interconnects 108L in interconnect layers 110L(1)-110L(N) are also separated by the inter-layer dielectric material 116 and interconnected in the third (Z-axis) direction by vias 118. The THVs 104 may couple an interconnect 108U on the first surface 112U to one of the interconnects 108L on the second surface 112L.

At least one IC may be attached (e.g., adhesively) to the inter-layer dielectric material 116 on either the first surface 112U or the second surface 112L of the package substrate 100 and electrically coupled (e.g., using additional vias in the third (Z-axis) direction) to the interconnects 108U, 108L. In this manner, electrical circuits, such as processors and/or logic circuits comprising transistor circuits, may be coupled to electrical circuits on other ICs coupled to the package substrate and/or may be coupled to external circuits. In some examples, the package substrate 100 may be configured to couple to ICs on the first surface 112U and to a power source (not shown) on the second surface 112L. In such examples, current is provided in the third direction from the second surface 112L to the first surface 112U through the THVs 104. The one or more ICs disposed on the first surface 112U of the package substrate 100 may have high power demands, and the power demands of the respective ICs may vary frequently and suddenly. To ensure a broad distribution of power with a low direct current (DC) resistance, a power signal (e.g., VDD) may be provided from the second surface 112L to the first surface 112U through many of the THVs 104.

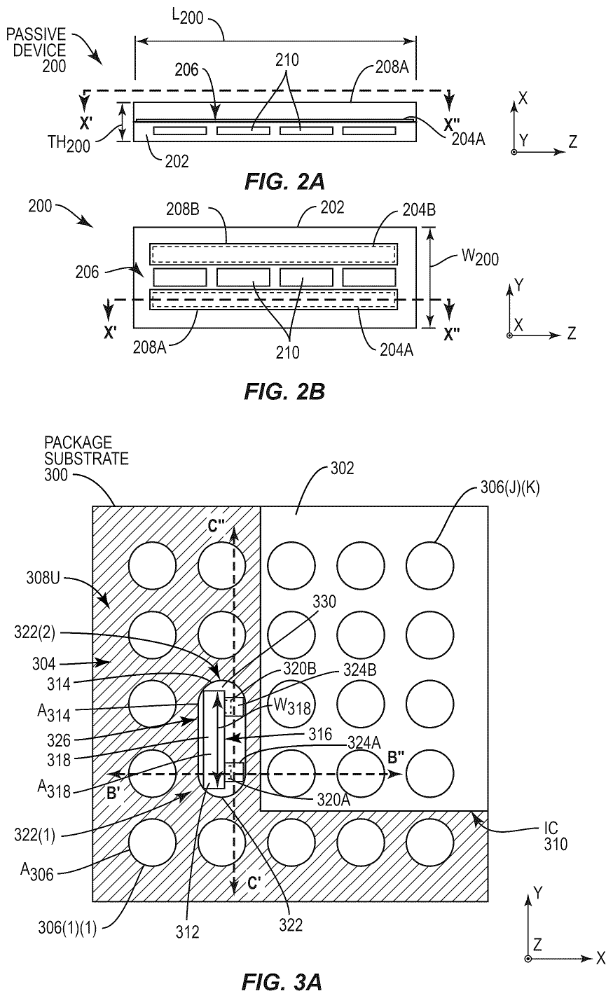

As the power demands of the circuits in an IC fluctuate, such as when the current draw suddenly increases, there may be a corresponding droop in the voltage of the power signal VDD, which can affect performance of the circuits on the ICs. To mitigate this problem, designers of IC packages (e.g., packages including the package substrate 100 and ICs disposed thereon) couple the power signal VDD to decoupling capacitors and/or other passive circuit components, as shown in more detail with reference to FIGS. 2A and 2B. The following description refers to decoupling capacitors as an example of the passive circuit components that may be employed by the ICs on the package substrate 100, but it should be understood that such description may be applicable in some aspect to any passive circuit components, such as inductors and resistors.

In some examples, decoupling capacitors may be coupled to the power signal VDD between a power source (not shown) and the package substrate 100. However, the benefit of decoupling capacitors decreases with the distance (e.g., length of an electrical trace) from the electrical circuits consuming the power. In this regard, it would be preferable to place the decoupling capacitors within the ICs themselves. However, adding passive devices directly to an IC may significantly increase the area of the IC, which increases the cost of the IC.

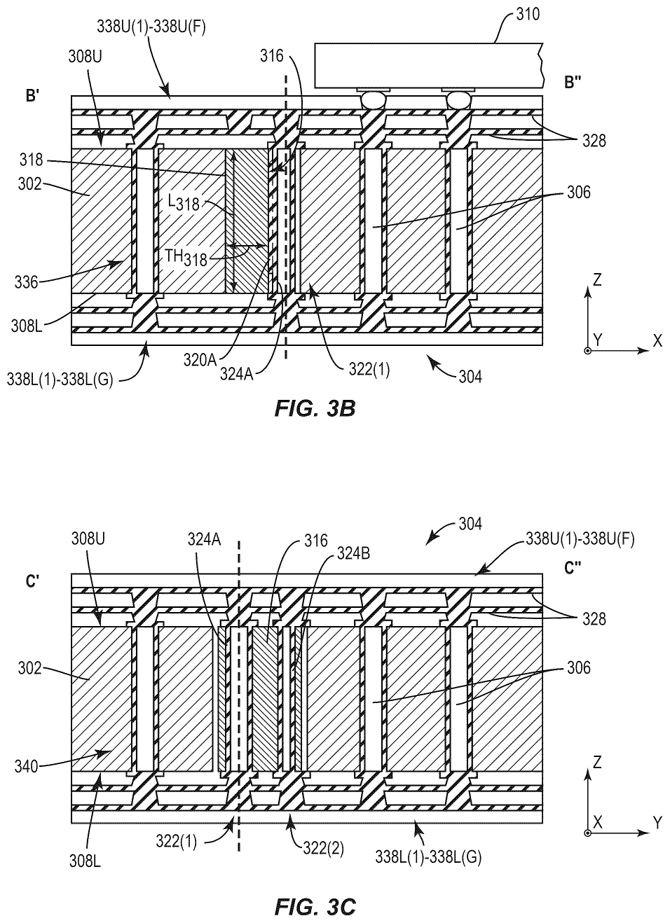

An intermediate solution to the above problem, as discussed with reference to FIGS. 3A-3C, is to include passive devices on the package substrate 100. First, however, an example of an exemplary passive device 200 is described with reference to FIGS. 2A and 2B. FIG. 2A is a cross-sectional side view of the passive device 200, which is formed in a device substrate 202 and includes an electrical contact 204A on a surface 206 of the device substrate 202. The electrical contact 204A, as shown in FIG. 2A, may be coupled to a via 208A. FIG. 2B is a plan view of the surface 206 of the device substrate 202 of the passive device 200 in FIG. 2A, showing that the passive device includes two electrical contacts 204A and 204B, which may be coupled to respective via 208A, 208B.

The device substrate 202 in FIGS. 2A and 2B has a length L₂₀₀ extending in the Z-axis direction and a width W₂₀₀ extending in the Y-axis direction. The device substrate 202 also has a thickness TH₂₀₀ extending in the X-axis direction. Accordingly, the electrical contacts 204A, 204B extend parallel to each other in the Z-axis direction. The electrical contacts 204A, 204B may be rectangular in shape and have longitudinal axes that extend in the third (Z-axis) direction. The device substrate 202 may comprise any appropriate material, such as silicon, in which one or more passive circuit components (which may be “capacitors”) 210 may be formed by known methods. For example, the passive circuit components 210 in the passive device 200 may comprise one or more capacitors 210 disposed in the device substrate 202 and coupled to each of the electrical contacts 204A, 204B. In some examples, the capacitors 210 may be trench capacitors. In some examples, the passive circuit components 210 may be inductors. Terminals of the passive circuit components 210 are coupled to the electrical contacts 204A, 204B. The passive device 200 may be employed in an exemplary package substrate 300, as illustrated in FIGS. 3A-3C.

FIG. 3A is a view of an exemplary package substrate 300 of a dielectric material 302 extending in a first, X-axis direction and a second, Y-axis direction and a 2D array 304 of cylindrical THVs 306(1)(1)-306(J)(K) (collectively “THVs 306”) extending through the dielectric material 302 in the third (Z-axis) direction. The following description of the package substrate 300 includes references to features that may be shown in any but not necessarily all of FIGS. 3A-3C, as appropriate. The view in FIG. 3A may be a view of a first, upper surface 308U of the dielectric material 302 extending in the first (X-axis) direction and the second (Y-axis) direction. The first surface 308U may be configured to couple to at least one IC 310 (see FIG. 3B). In an exemplary aspect, the package substrate 300 includes a passive device 312 disposed in a cavity 314 that extends through the dielectric material 302 in the third (Z-axis) direction. Although not shown in this example, the cavity 314 may be directly under the IC 310.

The passive device 312 may be the passive device 200 in FIGS. 2A and 2B and includes a contact surface 316 of a device substrate 318. The contact surface 316 may be the surface 206 of the device substrate 202 in FIGS. 2A and 2B. Accordingly, the passive device 312 may include electrical contacts 320A, 320B disposed on the contact surface 316. In an exemplary aspect, the passive device 312 is oriented in the cavity 314 with the contact surface 316 extending in the third (Z-axis) direction. Thus, in this orientation, the contact surface 316 may be referred to as a side surface 316.

In FIG. 3A, it can be seen that in this example, the cavity 314 comprises a first area A₃₁₄ of the first surface 308U corresponding to locations 322(1)-322(2) from which two adjacent cylindrical THVs 306 of the 2D array 304 are excluded. By excluding or omitting the THVs 306(2)(2) and 306(2)(3) from the locations 322(1)-322(2) in the 2D array 304 and instead forming the cavity 314 to accommodate the passive device 312, the benefit of locating the passive device 312 a short distance from the IC 310 may be realized. In addition, the cavity 314 may also include vias 324A, 324B coupled to the electrical contacts 320A, 320B of the passive device 312, as follows.

A cavity opening 326, having the area A₃₁₄ extends in the first (X-axis) direction and the second (Y-axis) direction. The device substrate 318 of the passive device 312 has a cross-sectional area A₃₁₈ in the first direction and the second direction, and the area A₃₁₈ may be less than half (e.g., <½) of the area A₃₁₄ of the cavity opening 326. Thus, there is additional area in the cavity 314 for the vias 324A and 324B to be included and coupled to the electrical contacts 320A, 320B. Each of the vias 324A, 324B extends in the third (Z-axis) direction through the cavity and may couple to interconnects 328 (see FIGS. 3B and 3C). Although each of the vias 324A, 324B has a cross-sectional area A₃₂₄ orthogonal to the third (Z-axis) direction that is smaller than a cross-sectional area A₃₀₆ of the cylindrical THVs 306, the vias 324A, 324B may help to reduce a total DC resistance in the distribution of current between a second, lower surface 308L of the package substrate 300 and the first, upper surface 308U, while also providing a capacitive decoupling in close proximity to the IC 310.

A dielectric material 330 may also be disposed in the cavity 314 between, in the first (X-axis) direction and the second (Y-axis) direction, the device substrate 318 of the passive device 312 and a wall 332 of the cavity 314, where the wall 332 is the dielectric material 302 of the package substrate 300. It should be recognized that if the passive device 312 was oriented differently, such as with the contact surface 316 parallel to the first surface 308U of the package substrate 300, the passive device 312 would occupy significantly more of the first surface 308U, requiring a larger cavity occupying significantly more area of the first surface 308U, which would cause more of the THVs 306 to be excluded from the 2D array 304, causing an increase in the DC resistance of power distribution of the package substrate.

FIG. 3B is a view of a cross-section B′-B″ of the package substrate shown in FIG. 3A extending in the first direction and the third direction, which is orthogonal to the view in FIG. 3A. FIG. 3B shows a row 336 in the 2D array 304 of cylindrical THVs 306 extending in the first (X-axis) direction through the dielectric material 302 and the first electrical contact 320A on the contact surface 316 of the device substrate 318 and coupled to the via 324A. FIG. 3B shows that a length L₃₁₈ of the device substrate 318 disposed in the cavity 314 extends in the third (Z-axis) direction, and the length L₃₁₈ may be less than or equal to the thickness TH 302 from the first surface 308U to the second surface 308L of the dielectric material 302.

In some examples, the length L₃₁₈ of the device substrate 318 of the passive device 312 may be in a range of one (1) millimeter (e.g., 1,000 microns) to two (2) millimeters. The thickness TH₃₀₂ of the dielectric material 302 in the third direction may be 1 to 2 millimeters or larger. The width W₃₁₈ of the device substrate 318 may be in a range of three hundred (300) to eight hundred (800) microns and a thickness TH₃₁₈ of the device substrate 318 may be in a range of fifty (50) to two hundred (200) microns.

In some examples, a first aspect ratio of the length L₃₁₈ of the device substrate 318 to the width W₃₁₈ of the device substrate 318 may be in a range of two-to-one (2:1) to four-to-one (4:1) and an aspect ratio of the length L₃₁₈ of the device substrate 318 to the thickness TH₃₁₈ of the device substrate 318 may be in a range of ten-to-one (10:1) to twenty-to-one (20:1).

As shown in FIG. 3B, one of the cylindrical THVs 306 is excluded from the row 336 in a location 322(1), where the cavity 314 is formed and a via 324A is formed in the cavity 314, which may be after the passive device 312 is disposed therein. FIG. 3B also shows interconnect layers 338U(1)-338U(F) on the first surface 308U of the dielectric material 302 and interconnect layers 338L(1)-338L(G) on the second surface 308L of the dielectric material 302. FIG. 3B shows that the via 324A may couple the electrical contact 320A to one of the interconnect layers 338U(1)-338U(F) and one of the interconnect layers 338L(1)-338L(G) to conduct a current through the package substrate 300 to an IC 310 mounted thereon.

FIG. 3C is a view of a cross-section C′-C″ extending in the second (Y-axis) direction and the third (Z-axis) direction, showing a column 340 of cylindrical THVs 306 in the 2D array 304 extending in the second direction through the dielectric material 302, and the contact surface 316 of the passive device including both of the electrical contacts 320A, 320B coupled to vias 324A, 324B, respectively. This view shows that the cavity 314 may occupy locations 322(1)-322(2) from which two adjacent THVs 306 are excluded to accommodate the passive device 312. FIG. 3C shows that the via 324A is electrically coupled to the first electrical contact 320A and the via 324B is electrically coupled to the second electrical contact 320B. The vias 324A and 324B may couple the electrical contacts 320A, 320B to interconnects 342U in any of the interconnect layers 338U(1)-338U(F) and interconnects 342L in any of the interconnect layers 338L(1)-338L(G).

Although not shown here, in some examples, the cavity 314 formed for the passive device 312 may include additional locations, in addition to locations 322(1) and 322(2), corresponding to additional THVs 306 that may be excluded from the 2D array 304. In such examples, an additional via (e.g., 324C) may be formed to couple the interconnect layers 338U(1)-338U(F) to the interconnect layers 338L(1)-338L(G) and may also couple to another electrical contact (e.g., 320C) of the passive device, which may include a plurality of passive circuit components. For example, the three vias (e.g., 324A, 324B and a third) in such examples may be in the X-axis direction (like row 336) or in the Y-axis direction (like column 340), or another appropriate via pattern.

It should be understood that the package substrate 300 may include a plurality of cavities 314 in which passive devices 312 are disposed to provide capacitive decoupling in multiple locations in the power distribution network provided in the package substrate 300 by the cylindrical THVs 306 and the vias 324A, 324B.

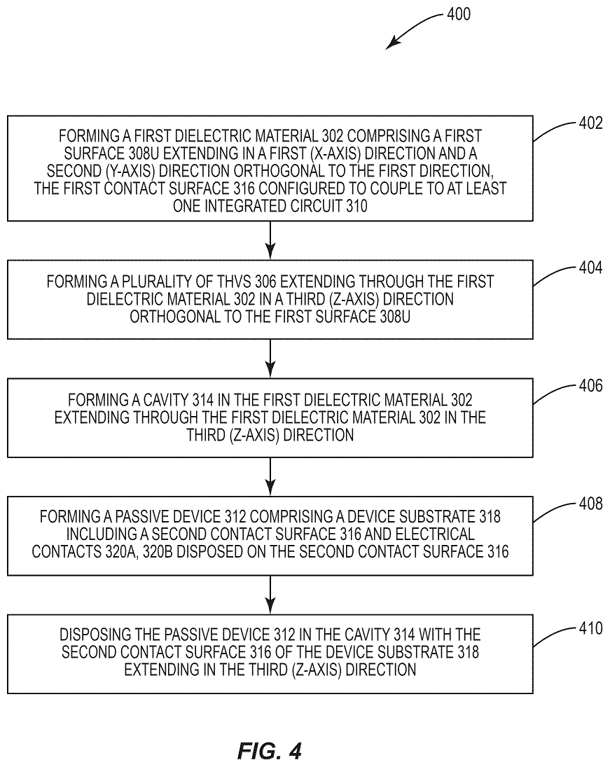

FIG. 4 is a flowchart illustrating a first exemplary method 400 of fabricating the package substrate 300 in FIGS. 3A-3C, including a passive device 312. The method includes forming a first dielectric material 302, including a first surface 308U extending in a first (X-axis) direction and a second (Y-axis) direction orthogonal to the first direction, the first contact surface 316 configured to couple to at least one integrated circuit (IC) 310 (block 402), forming a plurality of THVs 306 extending through the first dielectric material 302 in a third (Z-axis) direction orthogonal to the first surface 308U (block 404), and forming a cavity 314 in the first dielectric material 302 extending through the first dielectric material 302 in the third (Z-axis) direction (block 406). The method 400 further includes forming a passive device 312 including a device substrate 318 including a second contact surface 316 and electrical contacts 320A, 320B disposed on the second contact surface 316 (block 408) and disposing the passive device 312 in the cavity 314 with the second contact surface 316 of the device substrate 318 extending in the third (Z-axis) direction (block 410).

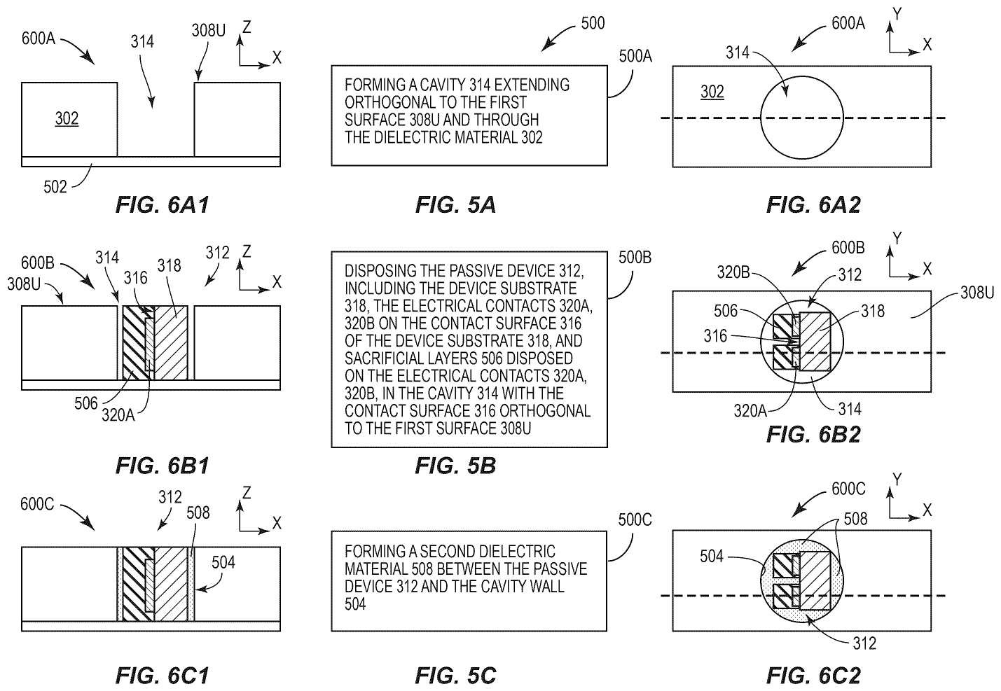

FIGS. 5A-5E are a flow chart of a method 500 of fabricating the package substrate 300 in FIGS. 3A-3C as illustrated in fabrication stages 600A-600E which include disposing the passive device 312 in the cavity 314 in the dielectric material 302 with electrical contacts 320A, 320B on a contact surface 316 extending in a direction orthogonal to the first surface 308U of the dielectric material 302 to reduce a number of cylindrical THVs 306 excluded from the 2D array 304 to accommodate the embedded passive device 312.

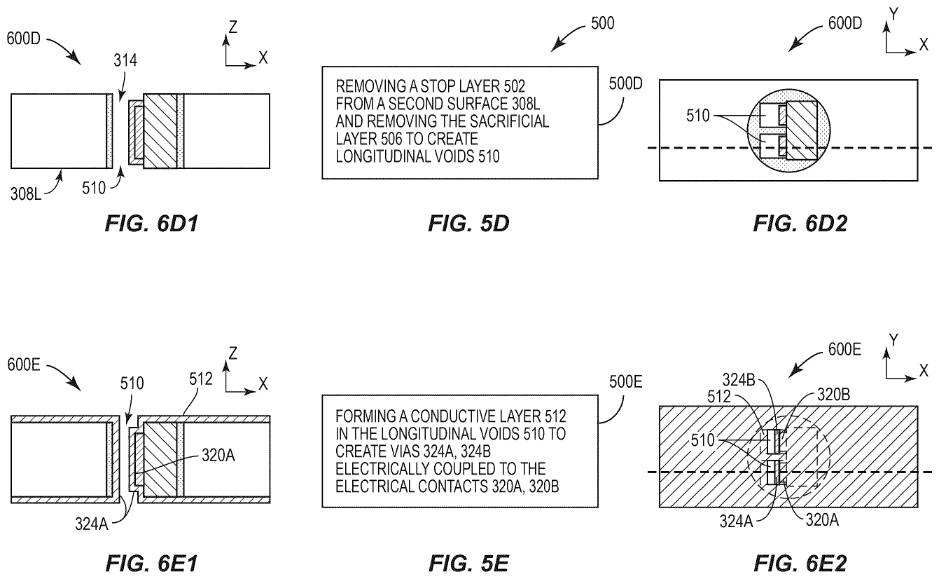

Fabrication of the package substrate 300 is shown at fabrication stages 600A-600E illustrated in cross-sectional side views in FIGS. 6A1-6E1 and plan views in FIGS. 6A2-6E2. The side views 6A1-6E1 correspond to cross-sections indicated in the plan views 6A2-6E2. In FIG. 5A, the method 500 includes, at fabrication stage 600A, forming a cavity 314 extending orthogonal to the first surface 308U and through the dielectric material 302 (block 500A). A stop layer 502 may be disposed on the second surface 308L of the dielectric material 302, and the cavity 314 may extend through the dielectric material 302 from the first surface 308U to the stop layer 502. An area A₃₁₄ of the cavity opening 326 may be determined by a width W₃₁₈ of the device substrate 318 and a thickness TH₃₁₈ of the device substrate 318. A cavity wall 504 of the cavity 314 may extend orthogonal to the first surface 308U.

In FIG. 5B, the method 500 includes, at fabrication stage 600B, disposing the passive device 312, including the device substrate 318, the electrical contacts 320A, 320B on the contact surface 316 of the device substrate 318, and sacrificial layers 506 disposed on the electrical contacts 320A, 320B, in the cavity 314 with the contact surface 316 orthogonal to the first surface 308U (block 500B). The sacrificial layer 506 may be a layer of photoresist material.

In FIG. 5C, the method 500 includes, at fabrication stage 600C, forming a second dielectric material 508 between the passive device 312 and the cavity wall 504 (block 500C). The second dielectric material 508 may be employed to isolate and secure the passive device 312 in the cavity 314.

In FIG. 5D, the method 500 includes, at fabrication stage 600D, removing the stop layer 502 (see FIG. 6A1) from the second surface 308L and removing the sacrificial layer 506 from the cavity 314 to create longitudinal voids 510 (block 500D).

In FIG. 5E, the method 500 includes, at fabrication stage 600E, forming a conductive layer 512 in the longitudinal voids 510 to create vias 324A, 324B electrically coupled to the electrical contacts 320A, 320B (block 500E). Although not shown, the conductive layer 512 may be removed from the first surface 308U and the second surface 308L. The vias 324A, 324B may be employed to couple the electrical contacts 320A, 320B to the interconnect layers 338U(1)-338 (F) on the first surface 308U and the interconnect layers 338L(1)-338L(G) on the second surface 308L. The interconnect layers 338U(1)-338U(F) may also be coupled to an IC 310 on the first surface 308U, and the interconnect layers 338L(1)-338L(G) may be coupled to a power source. In this manner, the passive device 312 may provide decoupling capacitance of power provided to the IC 310.

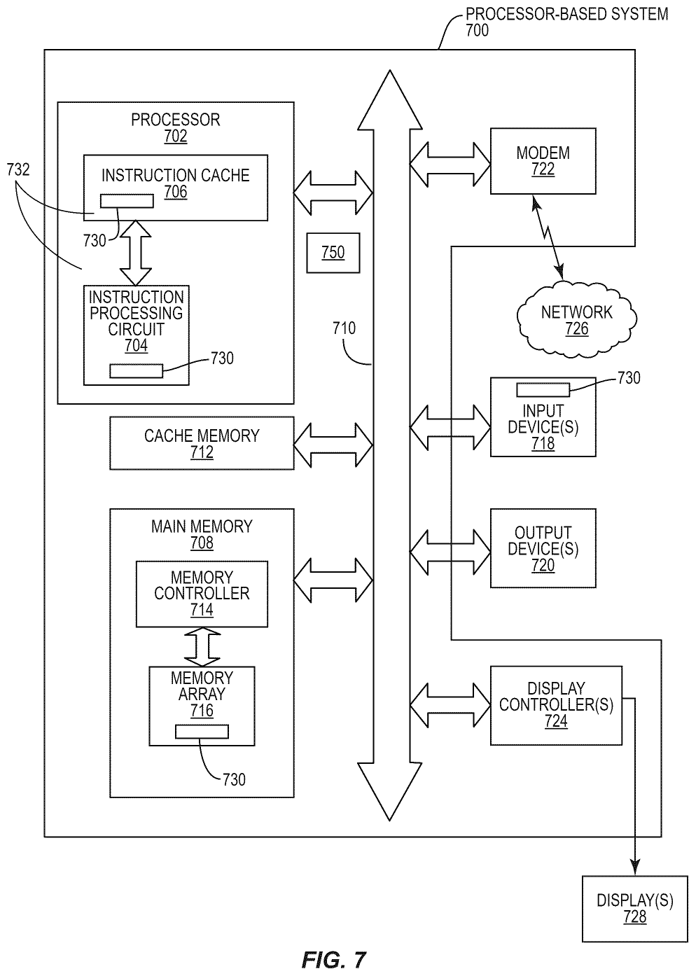

FIG. 7 is a block diagram of an exemplary processor-based system 700 that includes a processor 702 (e.g., a microprocessor), including an instruction processing circuit 704. The processor-based system 700 may include integrated circuits on an electronic board or card, such as a printed circuit board (PCB), in a server, a personal computer, a desktop computer, a laptop computer, a personal digital assistant (PDA), a computing pad, a mobile device, or any other device, and may represent, for example, a server, or a user's computer. The processor-based system 700 may include one or more passive devices 750, such as the passive device 312 in FIGS. 3A-3C. In this example, the processor-based system 700 includes the processor 702. The processor 702 represents one or more general-purpose processing circuits, such as a microprocessor, central processing unit, or the like. More particularly, the processor 702 may be an EDGE instruction set microprocessor or other processor implementing an instruction set that supports explicit consumer naming for communicating produced values resulting from the execution of producer instructions.

The processor 702 is configured to execute instructions for performing the operations and steps discussed herein. In this example, the processor 702 includes an instruction cache 706 for temporary, fast access memory storage of instructions accessible by the instruction processing circuit 704. Fetched or prefetched instructions from a memory, such as a main memory 708, over a system bus 710, are stored in the instruction cache 706. Data may be stored in a cache memory 712 coupled to the system bus 710 for low-latency access by the processor 702. The instruction processing circuit 704 is configured to process instructions fetched into the instruction cache 706 and process the instructions for execution.

The processor 702 and the main memory 708 are coupled to the system bus 710 and can intercouple peripheral devices included in the processor-based system 700. As is well known, the processor 702 communicates with these other devices by exchanging address, control, and data information over the system bus 710. For example, the processor 702 can communicate bus transaction requests to a memory controller 714 in the main memory 708 as an example of a slave device. Although not illustrated in FIG. 7, multiple system buses 710 could be provided, wherein each system bus 710 constitutes a different fabric. In this example, the memory controller 714 is configured to provide memory access requests to a memory array 716 in the main memory 708. The memory array 716 is comprised of an array of storage bit cells for storing data. The main memory 708 may be a read-only memory (ROM), flash memory, dynamic random-access memory (DRAM), such as synchronous DRAM (SDRAM), etc. and/or static memory (e.g., flash memory, SRAM, etc.), as non-limiting examples.

Other devices can be connected to the system bus 710. As illustrated in FIG. 7, these devices can include the main memory 708, one or more input device(s) 718, one or more output device(s) 720, a modem 722, and one or more display controllers 724, as examples. The input device(s) 718 can include any type of input device, including but not limited to input keys, switches, voice processors, etc. The output device(s) 720 can include any type of output device, including but not limited to audio, video, other visual indicators, etc. The modem 722 can be any device configured to allow an exchange of data to and from a network 726. The network 726 can be any type of network, including but not limited to a wired network (e.g., ethernet) or wireless network, a private or public network, a local area network (LAN), a wireless local area network (WLAN), a wide area network (WAN), a BLUETOOTH™ network, and the Internet. The modem 722 can be configured to support any type of communications protocol desired. The processor 702 may also be configured to access the display controller(s) 724 over the system bus 710 to control information sent to one or more displays 728. The display(s) 728 can include any type of display, including but not limited to a cathode ray tube (CRT), a liquid crystal display (LCD), a plasma display, etc.

The processor-based system 700 in FIG. 7 may include a set of instructions 730 to be executed by the processor 702 for any application desired according to the instructions. The instructions 730 may be stored in the main memory 708, the processor 702, and/or the instruction cache 706 as examples of a non-transitory computer-readable medium 732. The instructions 730 may also reside, completely or at least partially, within the main memory 708 and/or within the processor 702 during their execution. The instructions 730 may further be transmitted or received over the network 726 via the modem 722, such that the network 726 includes the computer-readable medium 732.

While the computer-readable medium 732 is shown in an exemplary embodiment to be a single medium, the term “computer-readable medium” should be taken to include a single medium or multiple media (e.g., a centralized or distributed database and/or associated caches and servers) that store the one or more sets of instructions. The term “computer-readable medium” shall also be taken to include any medium that is capable of storing, encoding, or carrying a set of instructions for execution by the processing device and that causes the processing device to perform any one or more of the methodologies of the embodiments disclosed herein. The term “computer-readable medium” shall accordingly be taken to include, but not be limited to, solid-state memories, optical medium, and magnetic medium.

The embodiments disclosed herein include various steps. The steps of the embodiments disclosed herein may be formed by hardware components or may be embodied in machine-executable instructions, which may be used to cause a general-purpose or special-purpose processor programmed with the instructions to perform the steps. Alternatively, the steps may be performed by a combination of hardware and software.

The embodiments disclosed herein may be provided as a computer program product or software that may include a machine-readable medium (or a computer-readable medium) having stored thereon instructions, which may be used to program a computer system (or other electronic devices) to perform a process according to the embodiments disclosed herein. A machine-readable medium includes any mechanism for storing or transmitting information in a form readable by a machine (e.g., a computer). For example, a machine-readable medium includes a machine-readable storage medium (e.g., ROM, random access memory (“RAM”), a magnetic disk storage medium, an optical storage medium, flash memory devices, etc.), and the like.

Unless specifically stated otherwise and as apparent from the previous discussion, it is appreciated that throughout the description, discussions utilizing terms such as “processing,” “computing,” “determining,” “displaying,” or the like refer to the action and processes of a computer system, or similar electronic computing device, that manipulates and transforms data and memories represented as physical (electronic) quantities within the computer system's registers into other data similarly represented as physical quantities within the computer system memories or registers or other such information storage, transmission, or display devices.

The algorithms and displays presented herein are not inherently related to any particular computer or other apparatus. Various systems may be used with programs in accordance with the teachings herein, or it may prove convenient to construct more specialized apparatuses to perform the required method steps. The required structure for a variety of these systems will appear from the description above. In addition, the embodiments described herein are not described with reference to any particular programming language. It will be appreciated that a variety of programming languages may be used to implement the teachings of the embodiments as described herein.

Those of skill in the art will further appreciate that the various illustrative logical blocks, modules, circuits, and algorithms described in connection with the embodiments disclosed herein may be implemented as electronic hardware, instructions stored in memory or in another computer-readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends on the particular application, design choices, and/or design constraints imposed on the overall system. Skilled artisans may implement the described functionality in varying ways for each particular application, but such implementation decisions should not be interpreted as causing a departure from the scope of the present embodiments.

The various illustrative logical blocks, modules, and circuits described in connection with the embodiments disclosed herein may be implemented or performed with a processor, a Digital Signal Processor (DSP), an Application Specific Integrated Circuit (ASIC), a Field Programmable Gate Array (FPGA), or other programmable logic device, a discrete gate or transistor logic, discrete hardware components, or any combination thereof designed to perform the functions described herein. Furthermore, a controller may be a processor. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The embodiments disclosed herein may be embodied in hardware and in instructions that are stored in hardware and may reside, for example, in RAM, flash memory, ROM, Electrically Programmable ROM (EPROM), Electrically Erasable Programmable ROM (EEPROM), registers, a hard disk, a removable disk, a CD-ROM, or any other form of computer-readable medium known in the art. An exemplary storage medium is coupled to the processor such that the processor can read information from and write information to the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary embodiments herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary embodiments may be combined. Those of skill in the art will also understand that information and signals may be represented using any of a variety of technologies and techniques. For example, data, instructions, commands, information, signals, bits, symbols, and chips that may be referenced throughout the above description may be represented by voltages, currents, electromagnetic waves, magnetic fields, optical fields, or particles, or any combination thereof.

Unless otherwise expressly stated, it is in no way intended that any method set forth herein be construed as requiring that its steps be performed in a specific order. Accordingly, where a method claim does not actually recite an order to be followed by its steps, or it is not otherwise specifically stated in the claims or descriptions that the steps are to be limited to a specific order, it is in no way intended that any particular order be inferred.

It will be apparent to those skilled in the art that various modifications and variations can be made without departing from the spirit or scope of the invention. Since modifications, combinations, sub-combinations, and variations of the disclosed embodiments incorporating the spirit and substance of the invention may occur to persons skilled in the art, the invention should be construed to include everything within the scope of the appended claims and their equivalents.

What is claimed is:

1. A package substrate, comprising:
a first dielectric material comprising a first surface extending in a first direction and in a second direction orthogonal to the first direction, the first surface configured to couple to at least one integrated circuit (IC);
a plurality of through-hole vias (THVs) extending through the first dielectric material in a third direction orthogonal to the first surface;
a cavity extending through the first dielectric material in the third direction; and
a passive device comprising:
a device substrate comprising a contact surface; and
electrical contacts disposed on the contact surface;
wherein:
the passive device is disposed in the cavity; and
the contact surface of the device substrate extends in the third direction.

2. The package substrate of claim 1, wherein:
the plurality of THVs comprises a two-dimensional (2D) array of cylindrical THVs in the first surface of the first dielectric material; and
the cavity comprises a first area of the first surface corresponding to locations from which two adjacent cylindrical THVs of the 2D array are excluded.

3. The package substrate of claim 2, wherein:
a length of the device substrate of the passive device disposed in the cavity extends in the third direction; and
the length of the device substrate is less than or equal to a thickness from the first surface to a second surface of the first dielectric material.

4. The package substrate of claim 3, wherein:
a first cross-sectional area of the device substrate in the first direction and the second direction is less than half of the first area of the cavity.

5. The package substrate of claim 2, further comprising a first via and a second via, each extending through the cavity in the third direction and each having a first cross-sectional area orthogonal to the third direction smaller than a second cross-sectional area of a first one of the cylindrical THVs.

6. The package substrate of claim 5, wherein:
the first via is electrically coupled to a first electrical contact of the electrical contacts; and
the second via is electrically coupled to a second electrical contact of the electrical contacts.

7. The package substrate of claim 6, wherein the electrical contacts comprise rectangular contacts comprising longitudinal axes extending in the third direction.

8. The package substrate of claim 7, further comprising interconnect layers disposed on the first surface, wherein the first via and the second via are electrically coupled to respective interconnects in the interconnect layers.

9. The package substrate of claim 4, further comprising a second dielectric material disposed directly between, in the first direction and the second direction, the passive device and a wall of the cavity.

10. The package substrate of claim 1, wherein the passive device comprises a capacitor.

11. The package substrate of claim 10, wherein the capacitor comprises a trench capacitor.

12. The package substrate of claim 3, wherein:
the length of the device substrate of the passive device is in a first range of one (1) to two (2) millimeters;
a width of the device substrate of the passive device is in a second range of three hundred (300) to eight hundred (800) microns; and
a thickness of the device substrate of the passive device is in a third range of fifty (50) to two hundred (200) microns.

13. The package substrate of claim 3, wherein:
a first aspect ratio of the length of the passive device to a width of the passive device is in a range of two-to-one (2:1) to four-to-one (4:1); and
a second aspect ratio of the length of the passive device to a thickness of the passive device is in a range of ten-to-one (10:1) to twenty-to-one (20:1).

14. A method of fabricating a package substrate comprising a passive device, the method comprising:
forming a first dielectric material comprising a first surface extending in a first direction and in a second direction orthogonal to the first direction, the first surface configured to couple to at least one integrated circuit (IC);
forming a plurality of through-hole vias (THVs) extending through the first dielectric material in a third direction orthogonal to the first surface;
forming a cavity in the first dielectric material extending through the first dielectric material in the third direction;
forming the passive device comprising:
a device substrate comprising a contact surface; and
electrical contacts disposed on the contact surface; and
disposing the passive device in the cavity with the contact surface of the device substrate extending in the third direction.

15. The method of claim 14, wherein forming the plurality of THVs further comprises:
forming cylindrical THVs in a two-dimensional (2D) array of THV locations in the first surface of the first dielectric material; and
forming a cavity opening of the cavity having a first area corresponding to a first THV location and a second THV location of the 2D array.

16. The method of claim 14, wherein forming the passive device further comprises disposing a sacrificial layer extending longitudinally in a length direction of the passive device and in contact with the electrical contacts.

17. The method of claim 16, further comprising:
removing the sacrificial layer from within the cavity to create longitudinal voids; and
disposing a conductive layer in the longitudinal voids in contact with the electrical contacts to form a first via and a second via extending in the length direction of the passive device through the first dielectric material.

18. The method of claim 14, further comprising disposing a second dielectric material directly between the passive device and a cavity wall of the cavity.

19. The method of claim 14, further comprising forming interconnect layers on the first surface above the cavity in the third direction, wherein the first via and the second via are electrically coupled to respective interconnects in the interconnect layers.

20. The method of claim 14, wherein forming the passive device further comprises forming a trench capacitor.
